(19) United States
(12) Patent Application Publication
(10) Pub. No.: US 2025/0151588 A1
(43) Pub. Date: May 8, 2025

(54) DISPLAY APPARATUS

(71) Applicant: LG Display Co., Ltd., Seoul (KR)

(72) Inventor: Howon CHOI, Paju-si (KR)

(73) Assignee: LG Display Co., Ltd., Seoul (KR)

(21) Appl. No.: 18/929,267

(22) Filed: Oct. 28, 2024

(30) Foreign Application Priority Data
Nov. 3, 2023 (KR) 10-2023-0150977

(51) Int. Cl. H10K 59/80; H10K 59/38; H10K 102/00

(52) U.S. Cl. CPC H10K 59/879; H10K 59/38; H10K 2102/351

(57) ABSTRACT

A display panel can include first and second subpixels on a substrate and adjacent to each other, and the first and second subpixels each including a first electrode, an emission layer and a second electrode. The display panel includes a first insulation layer between the emission layer and the substrate and including a first concave portion between a first emission area of the first subpixel and a second emission area of the second subpixel, a second insulation layer between the emission layer and the first insulation layer, the second insulation layer including a second concave portion between the first and second emission areas. Also, the second electrode extends across the second concave portion, a portion of the second electrode is in the second concave portion and is closer to the substrate than both of the first electrodes in the first and second subpixels or an upper surface of the first insulation layer.

### CROSS-REFERENCE TO RELATED APPLICATIONS

This application claims priority to Korean Patent Application No. 10-2023-0150977 filed in the Republic of Korea on Nov. 3, 2023, the entirety of which is hereby incorporated by reference into the present application as if fully set forth herein.

### BACKGROUND

### Field of the Invention

The present disclosure relates to a display apparatus having a bottom emission structure.

### Discussion of the Related Art

Display apparatuses can be classified into a bottom emission structure and a top emission structure, based on a direction in which emitted light is irradiated. Display apparatuses having the bottom emission structure can irradiate emitted light in a downward direction, and display apparatuses having the top emission structure can irradiate emitted light in an upward direction.

In display apparatuses having the bottom emission structure, research for enhancing light extraction efficiency by using a structure including a plurality layers provided under a light emitting device is being done.

However, enhancing the light extraction efficiency often involves including multiple layers or additional components, which can increase the thickness of the display device, increase the distance or space between subpixels impairing resolution, and use additional manufacturing steps that increase costs and production time. Also, light leakage can occur between adjacent subpixels which impair image quality, and outgassing from lower layers can reach the light emitting elements and decrease the life span of the display device.

Thus, there exists a need for a display apparatus having a bottom emission structure, which can improve light extraction, reduce the thickness of the display device, reduce power consumption, pack subpixels closer together for higher resolution, better prevent outgassing from reaching the light emitting elements, and reduce the number of manufacturing steps to save time and costs.

### SUMMARY OF THE DISCLOSURE

Accordingly, the present disclosure is directed to providing a display apparatus that substantially obviates one or more problems due to limitations and disadvantages of the related art.

An aspect of the present disclosure is directed to providing a display apparatus in which an aperture ratio and light extraction efficiency can be enhanced.

Another aspect of the present disclosure is directed to providing a display apparatus which can prevent the occurrence of a light leakage defect.

Another aspect of the present disclosure is directed to providing a display apparatus which can have high emission efficiency with low power.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

An object of the present disclosure is to provide a display panel that includes first and second subpixels disposed on a first substrate and adjacent to each other, each of the first and second subpixels including a first electrode, an emission layer and a second electrode, a first color filter disposed between a first emission area of the first subpixel and the first substrate, a second color filter disposed between a second emission area of the second subpixel and the first substrate, and an insulation layer disposed between the first and second emission areas and the first and second color filters. Also, a concave portion of the insulation layer is disposed between the first and the second emission areas, the second electrode extends across the concave portion, and a portion of the second electrode is disposed in the concave portion and is located closer to the first substrate than a lower surface of the first electrode.

Another object of the present disclosure is to provide a display panel that includes a first subpixel and second subpixel disposed on a first substrate, the first subpixel being adjacent to the second subpixel, and each of the first and second subpixels including a first electrode, an emission layer and a second electrode, a first color filter disposed between a first emission area of the first subpixel and the first substrate, a second color filter disposed between a second emission area of the second subpixel and the first substrate, a first insulation layer disposed between the first and second emission areas and the first and second color filters, a first concave portion of the first insulation layer being disposed between the first emission area and the second emission area, a second insulation layer disposed between the first and second emission areas and the first insulation layer, and a second concave portion of the second insulation layer being disposed between the first subpixel and the second subpixel, the second concave portion overlapping with the first concave portion, wherein the second electrode extends across the second concave portion of the second insulation layer, in which a portion of the second electrode is disposed in the second concave portion, the portion of the second electrode is located closer to the first substrate than both of the first electrode in the first subpixel and the first electrode in the second subpixel or is located closer to the first substrate than an upper surface of the first insulation layer.

An object of the present disclosure is to provide a display panel that includes a first subpixel and a second subpixel disposed on a substrate, the first subpixel being adjacent to the second subpixel, and each of the first and second subpixels including a first electrode, an emission layer and a second electrode, a first insulation layer disposed between the emission layer and the substrate, the first insulation layer including a first concave portion disposed between a first emission area of the first subpixel and a second emission area of the second subpixel; and a second insulation layer disposed between the emission layer and the first insulation layer, the second insulation layer including a second concave portion disposed between the first emission area and the second emission area, in which the second electrode extends across the second concave portion of the second insulation layer, a portion of the second electrode is disposed in the second concave portion, and the portion of the second electrode is located closer to the substrate than both of the first electrode in the first subpixel and the first electrode in the second subpixel, or is located closer to the substrate than an upper surface of the first insulation layer.

Another object of the present disclosure is to provide a display panel that includes a color filter layer disposed in at least one of the first subpixel and the second subpixel, in which the first insulation layer includes an opening region exposing at least a portion of the color filter layer.

An object of the present disclosure is to provide a display panel, in which the portion of the second electrode is configured to reflect light emitted from at least one of the first and second emissions areas in a direction toward the substrate.

Yet another object of the present disclosure is to provide a display panel, in which the second insulation layer has a second refractive index that is greater than a first refractive index of the first insulation layer.

Another object of the present disclosure is to provide a display panel in which a first thickness of the first insulation layer in an area overlapping with the first or second emission area is greater than a second thickness of the second insulation layer in an area overlapping with the first or second emission area.

An object of the present disclosure is to provide a display panel in which the second insulation layer has a third thickness corresponding to a center of the second concave portion, and the third thickness is less than or equal to the second thickness.

Another object of the present disclosure is to provide a display panel in which the first insulation layer includes a first slope surface corresponding to the first concave portion, the second insulation layer includes a second slope surface corresponding to the second concave portion, and the first slope surface is steeper than the second slope surface.

An object of the present disclosure is to provide a display panel in which the emission layer extends across both of the first and second subpixels, the emission layer includes a third slope surface corresponding to the second slope surface of the second insulation layer, the second electrode includes a fourth slope surface corresponding to the third slope surface of the emission layer, and an angle of the fourth slope surface of the second electrode corresponds to an angle of the second slope surface of the second insulation layer.

Yet another object of the present disclosure is to provide a display panel in which a lowermost portion of the second electrode between the first and second subpixels is disposed closer to the substrate than an upper surface of the first insulation layer.

An object of the present disclosure is to provide a display panel in which the first insulation layer includes an opening region corresponding to the first concave portion, the opening region being a hole that extends through opposite sides of the first insulation layer.

Another object of the present disclosure is to provide a display panel that includes a bank disposed on an edge of the first electrode in the first subpixel and on an edge of the first electrode in the second subpixel.

Yet another object of the present disclosure is to provide a display panel in which both of the first and second insulation layers extend continuously across a non-emission area between the first subpixel and the second subpixel, and the first insulation layer includes a first flat surface overlapping with at least one of the first and second emission areas, and a second flat surface overlapping with the non-emission area between the first subpixel and the second subpixel, the second flat surface being disposed closer to the substrate than the first flat surface.

An object of the present disclosure is to provide a display panel in which a cross section of the second electrode has a “V” shape or a “U” shape in a non-emission area between the first subpixel and the second subpixel.

Another object of the present disclosure is to provide a display panel in which the emission layer extends across both of the first and second subpixels, an outer edge of the first electrode in the first subpixel facing towards the first and second concave portions directly contacts the emission layer, and an outer edge of the first electrode in the second subpixel facing towards the first and second concave portions directly contacts the emission layer.

An object of the present disclosure is to provide a display panel in which a first slope surface of the first insulation layer has a slope which is greater than or equal to 70 degrees, and a second slope surface of the second organic insulation layer has a slope which is less than or equal to 45 degrees.

Another object of the present disclosure is to provide a display apparatus that includes a first organic insulation layer disposed on a substrate, the first organic insulation layer including a first slope surface between a first subpixel and a second subpixel, a second organic insulation layer disposed on the first organic insulation layer, the second organic insulation layer including a second slope surface between the first subpixel and the second subpixel and at least partially overlapping with the first slope surface, and a plurality of light emitting devices respectively disposed in the first subpixel and the second subpixel, on the second organic insulation layer, in which the second slope surface of the second organic insulation layer has a slope which is less than a slope of the first slope surface of the first organic insulation layer.

An object of the present disclosure is to provide a display apparatus in which the first organic insulation layer is thicker than the second organic insulation layer.

Yet another object of the present disclosure is to provide a display apparatus in which the first organic insulation layer has a lower refractive index than the second organic insulation layer.

An object of the present disclosure is to provide a display apparatus in which the first slope surface of the first organic insulation layer has a slope which is greater than or equal to 70 degrees.

Another object of the present disclosure is to provide a display apparatus in which the second slope surface of the second organic insulation layer has a slope which is less than or equal to 45 degrees.

Another object of the present disclosure is to provide a display apparatus in which the first organic insulation layer includes an organic material having a viscosity which is higher than a viscosity of the second organic insulation layer.

An object of the present disclosure is to provide a display apparatus in which the first organic insulation layer includes an opening region between the first subpixel and the second subpixel, and the second organic insulation layer covers the opening region of the first organic insulation layer.

Yet another object of the present disclosure is to provide a display apparatus in which a thickness of the second organic insulation layer between the first subpixel and the second subpixel is thinner than a thickness of the second organic insulation layer in a region overlapping the first subpixel.

An object of the present disclosure is to provide a display apparatus in which the first organic insulation layer further includes a first flat surface in a region overlapping the first subpixel and a second flat surface disposed at a lower height than the first flat surface in a region between the first subpixel and the second subpixel, and the first slope surface connects the first flat surface to the second flat surface.

An object of the present disclosure is to provide a display apparatus that includes a plurality of color filters respectively provided in the first subpixel and the second subpixel, between the substrate and the first organic insulation layer.

An object of the present disclosure is to provide a display apparatus in which the first organic insulation layer includes an opening region exposing at least a portion of each of the plurality of color filters, between the first subpixel and the second subpixel, and the second organic insulation layer covers the at least a portion of each of the plurality of color filters exposed by the opening region, between the first subpixel and the second subpixel.

Another object of the present disclosure is to provide a display apparatus in which the plurality of color filters at least partially overlap each other between the first subpixel and the second subpixel.

Another object of the present disclosure is to provide a display apparatus in which each of the plurality of light emitting devices includes a first electrode on the second organic insulation layer, an emission layer on the first electrode, and a second electrode on the emission layer, in which the second electrode is a reflection electrode.

An object of the present disclosure is to provide a display apparatus in which the emission layer extends continuously across the first subpixel and the second subpixel and between the first subpixel and the second subpixel, and the emission layer contacts an entire region of the first electrode.

An object of the present disclosure is to provide a display apparatus in which the second electrode extends continuously across the first subpixel and the second subpixel and between the first subpixel and the second subpixel, and the second electrode extends along the second slope surface of the second organic insulation layer, between the first subpixel and the second subpixel.

Another object of the present disclosure is to provide a display apparatus that includes a bank disposed on the first electrode to cover an end of the first electrode.

According to the present disclosure, light which is emitted from a light emitting device and travels to a lateral surface can be reflected by the slope surface of the second electrode to change a path of light to a forward direction, thereby enhancing light extraction efficiency.

According to the present disclosure, an area of a non-emission region can be reduced, and an aperture ratio can be enhanced.

Moreover, according to the present disclosure, high emission efficiency can be realized with low power, and moreover, power consumption can decrease.

According to the present disclosure, a problem can be solved where water or oxygen penetrates into a light emitting device to degrade the light emitting device.

Moreover, according to the present disclosure, a total thickness of the first organic insulation layer and the second organic insulation layer can decrease and can thus prevent the occurrence of a light leakage phenomenon where light emitted from the light emitting device is leaked to an adjacent subpixel.

It is to be understood that both the foregoing general description and the following detailed description of the present disclosure are explanatory examples and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a perspective view illustrating a display apparatus according to an embodiment of the present disclosure;

FIG. 2 is a block diagram schematically illustrating a configuration of a display apparatus according to an embodiment of the present disclosure;

FIG. 3 is a plan view illustrating an example of a pixel included in a display apparatus according to an embodiment of the present disclosure;

FIG. 4 is a circuit diagram illustrating an example of a subpixel illustrated in FIG. 3 according to an embodiment of the present disclosure;

FIG. 5 is a cross-sectional view illustrating an embodiment of a subpixel taken along line I-I′ illustrated in FIG. 3 according to an embodiment of the present disclosure;

FIG. 6 is a cross-sectional view illustrating an example of a light path according to an embodiment of the present disclosure;

FIG. 7 is a cross-sectional view illustrating another embodiment of a subpixel taken along line I-I′ illustrated in FIG. 3;

FIG. 8 is a cross-sectional view illustrating an example of an ashing process on a second organic insulation layer according to an embodiment of the present disclosure;

FIG. 9 is a cross-sectional view illustrating another embodiment of a subpixel taken along line I-I′ illustrated in FIG. 3 according to an embodiment of the present disclosure; and

FIG. 10 is a cross-sectional view illustrating another embodiment of a subpixel taken along line I-I′ illustrated in FIG. 3.

### DETAILED DESCRIPTION OF THE EMBODIMENTS

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In a situation where “comprise,” “have,” and “include” described in the present specification are used, another part can be added unless “only” is used. The terms of a singular form can include plural forms unless referred to the contrary. In construing an element, the element is construed as including an error range although there is no explicit description. In describing a position relationship, for example, when a position relation between two parts is described as “on,” “over,” “under,” and “next,” one or more other parts can be disposed between the two parts unless “just” or “direct” is used. In describing a temporal relationship, for example, when the temporal order is described as “after,” “subsequent,” “next,” and “before,” a situation which is not continuous can be included, unless “just” or “direct” is used. It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in co-dependent relationship. Reference will now be made in detail to the example embodiments of the present disclosure, examples of which are illustrated in the accompanying drawings. Wherever possible, the same reference numbers will be used throughout the drawings to refer to the same or like parts.

Hereinafter, the embodiments of the present disclosure will be described in detail with reference to the accompanying drawings.

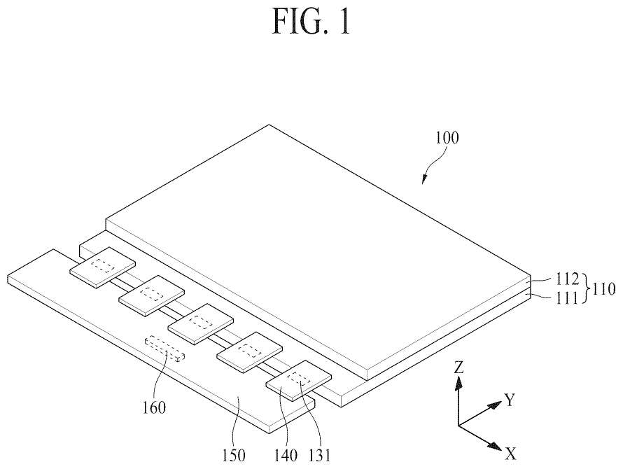

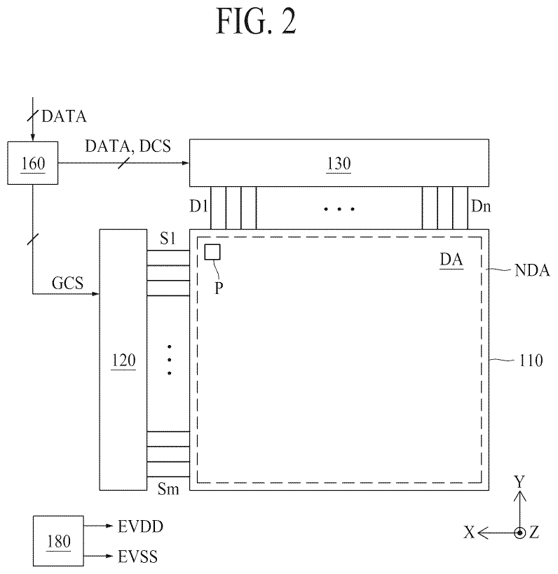

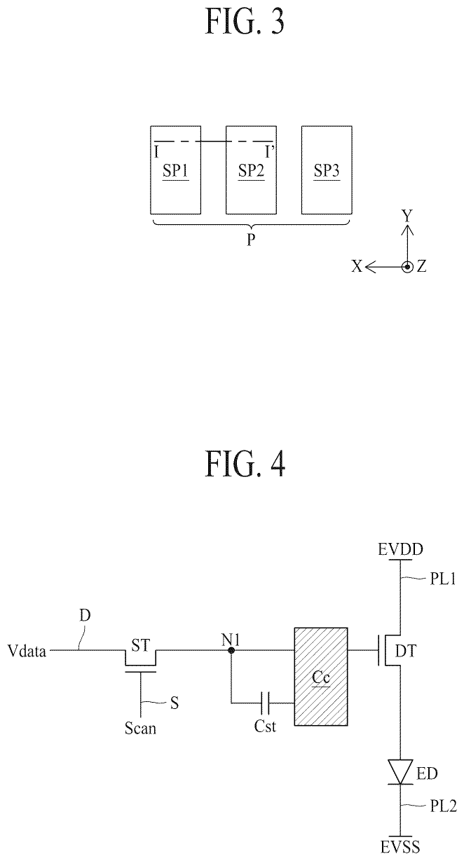

FIG. 1 is a perspective view illustrating a display apparatus 100 according to an embodiment of the present disclosure. FIG. 2 is a block diagram schematically illustrating a configuration of the display apparatus 100 according to an embodiment of the present disclosure. FIG. 3 is a plan view illustrating an example of a pixel included in the display apparatus 100 according to an embodiment of the present disclosure.

The display apparatus 100 according to an embodiment of the present disclosure can be described as being implemented as an organic light emitting display apparatus, but is not limited thereto and can be implemented as a liquid crystal display (LCD) apparatus, a quantum dot light emitting diode display apparatus, or an electrophoresis display apparatus.

Referring to FIGS. 1 and 2, the display apparatus 100 according to an embodiment of the present disclosure can include a display panel 110, a scan driver 120 embedded in the display panel 110, a data driver 130 connected to the display panel 110, a timing controller 160 controlling the scan driver 120 (e.g., gate driver) and the data driver 130, and a power circuit 180.

The display panel 110 can include a first substrate 111 and a second substrate 112. The second substrate 112 can be an encapsulation substrate. The first substrate 111 can include a plastic film or a glass substrate, but is not limited thereto. The first substrate 111 can include a semiconductor material such as a silicon wafer. The second substrate 112 can include a plastic film, a glass substrate, or an encapsulation film (e.g., a protection film).

The display apparatus 100 according to an embodiment of the present disclosure can be implemented as a bottom emission type where emitted light is irradiated downward. In this situation, a material of the first substrate 111 can use a transparent material, and a material of the second substrate 112 can use an opaque material as well as a transparent material.

The display panel 110 can include a display area DA and a non-display area NDA which is disposed outside the display area DA to surround the display area DA. The display panel 110 can include a plurality of pixels P which are provided in the display area DA to display an image. Each of the pixels P can include two or more subpixels SP. For example, as illustrated in FIG. 3, the pixel P can include a plurality of subpixels SP1, SP2, and SP3. The plurality of subpixels SP1, SP2 and SP3 can include a first subpixel SP1 emitting red light, a second subpixel SP2 emitting green light, and a third subpixel SP3 emitting blue light, but are not limited thereto. The plurality of subpixels SP1, SP2 and SP3 can further include a fourth subpixel SP4 emitting white light. Also, the arrangement order of the subpixels SP1 to SP3 can be variously changed.

Data lines D1 to Dn (where n can be a positive integer of 2 or more) and scan lines S1 to Sm (where m can be a positive integer of 2 or more), which are connected to the subpixels SP1 to SP3, can be provided in the display panel 110. The data lines D1 to Dn can be formed to intersect with the scan lines S1 to Sm. Each of the subpixels SP1 to SP3 of the display panel 110 can be connected to one of the data line D1 to Dn and one of the scan lines S1 to Sm. The data lines D1 to Dn can supply voltages, supplied from the data driver 130, to the subpixels SP1 to SP3. The scan lines S1 to Sm can supply a scan signal, supplied from the scan driver 120, to the subpixels SP1 to SP3.

Each of the subpixels SP1 to SP3 can be turned on by the scan signal, and when a data voltage of a data line is supplied to a gate electrode of a driving transistor, a light emitting device ED can emit light with a drain-source current of the driving transistor.

The scan driver 120 can be supplied with a scan control signal GCS from the timing controller 160. The scan driver 120 can supply scan signals or an emission control signal to the scan lines S1 to Sm by using the scan control signal GCS.

The scan driver 120 can be formed as a gate driver in panel (GIP) type in the non-display area NDA outside one side or both sides of the display area DA. Alternatively, the scan driver 120 can be manufactured as a driving chip and can be mounted on a flexible film, and moreover, can be attached on the non-display area NDA outside one side or both sides of the display area DA, based on a tape automated bonding (TAB) type.

The data driver 130 can be supplied with digital video data DATA and a data control signal DCS from the timing controller 160. The data driver 130 can convert the digital video data DATA into analog positive/negative data voltages by using the data control signal DCS and can supply the analog positive/negative data voltages to the data lines D1 to Dn.

The data driver 130 can include a plurality of data drive integrated chips (ICs) 131 as in FIG. 1. Each of the plurality of data drive ICs 131 can be mounted on the circuit film 140, based on a chip on film (COF) type, a chip on plastic (COP) type, a flexible printed circuit (FPC) type, or a flexible flat cable (FFC) type. The circuit film 140 can be attached on pads provided in the non-display area NDA of the display panel 110 by using an anisotropic conductive film, and thus, the plurality of data drive ICs 131 can be connected to the pads.

As shown in FIG. 1, a circuit board 150 can be attached on the circuit films 140. A plurality of circuits implemented as driving chips can be mounted on the circuit board 150. For example, the timing controller 160 can be mounted on the circuit board 150. The circuit board 150 can be a printed circuit board (PCB) or a flexible PCB (FPCB).

The timing controller 160 can be supplied with the digital video data DATA and timing signals from a host system. The timing signals can include a vertical synchronization signal, a horizontal synchronization signal, a data enable signal, and a dot clock. The vertical synchronization signal can be a signal which defines one frame period. The horizontal synchronization signal can be a signal which defines one horizontal period used to supply data voltages to pixels of one horizontal line of the display panel 110. The data enable signal can be a signal which defines a period where valid data is input. The dot clock can be a signal which is repeated at a short period.

The timing controller 160 can generate the data control signal DCS for controlling an operation timing of the data driver 130 and the scan control signal GCS for controlling an operation timing of the scan driver 120, based on the timing signals. The timing controller 160 can output the scan control signal GCS to the scan driver 120 and can output the digital video data DATA and the data control signal DCS to the data driver 130.

The power circuit 180 can generate and supply a plurality of driving voltages used for operations of all circuit elements of the display apparatus 100 by using an input voltage. The power circuit 180 can generate a first source voltage EVDD, a second source voltage EVSS, an initialization voltage (a reference voltage) Vref and can supply the generated voltages to the display panel 110. The lower circuit 180 can generate and supply various driving voltages used for operations of the gate driver 120, the data driver 130, and the timing controller 160.

FIG. 4 is a circuit diagram illustrating an example of a subpixel illustrated in FIG. 3 according to an embodiment of the present disclosure.

Referring to FIGS. 3 and 4, each of the subpixels SP1 to SP3 can have a 2T (transistor) 1C (capacitor) structure which includes two transistors DT and ST and one capacitor Cst, but embodiments of the present disclosure are not limited thereto. Each of the subpixels SP1 to SP3 can further include a compensation circuit CC. In this situation, each of the subpixels SP1 to SP3 can have various structures such as 3T1C, 4T2C, 5T2C, 6T1C, 6T2C, 7T1C, and 7T2C.

Each of the transistors DT and ST of each of the subpixels SP1 to SP3 can include a gate electrode, a source electrode, and a drain electrode. The source electrode and the drain electrode may not be fixed and can be changed based on a direction of each of a voltage and a current applied to the gate electrode, and thus, one of the source electrode and the drain electrode can be referred to as a first electrode and the other electrode can be referred to as a second electrode. The transistors DT and ST of each of the subpixels SP1 to SP3 can use at least one of a polysilicon semiconductor, an amorphous silicon semiconductor, and an oxide semiconductor. The transistors DT and ST can each be a P type, an N type, or a combination type of the P type and the N type.

The light emitting device ED can include an anode electrode connected to a driving transistor DT, a cathode electrode which is supplied with the second source voltage EVSS through a second power line PL2, and an emission layer between the anode electrode and the cathode electrode. The anode electrode can be an independent electrode for each light emitting device, and the cathode electrode can be a common electrode shared by all light emitting devices. When a driving current is supplied from the driving transistor DT to the light emitting device ED, an electron from the cathode electrode can be supplied to the emission layer, a hole from the anode electrode can be supplied to the emission layer, and the electron and the hole can be recombined in the emission layer to allow a fluorescent or phosphorous material to emit light, thereby emitting light having brightness proportional to a current value of the driving current.

In each of the subpixels SP1 to SP3, the driving transistor DT can be connected between the anode electrode of the light emitting device ED and a first power line PL1 which transfers the driving voltage EVDD. Here, the driving voltage EVDD can be applied to a first electrode of the driving transistor DT.

The driving transistor DT can be a transistor which drives the light emitting device ED and can be controlled by a voltage applied to the gate electrode, and thus, can supply a current to the light emitting device ED. Accordingly, the light emitting device ED can be driven.

In each of the subpixels SP1 to SP3, a switching transistor ST can be connected between a first node N1 of the driving transistor DT and a data line D. The switching transistor ST can be controlled by a scan signal Scan supplied through a scan line S to apply a data voltage Vdata, supplied through the data line D, to the first node N1.

In each of the subpixels SP1 to SP3, the capacitor Cst can be connected to the first node N1 and can be charged with a voltage applied to the first node N1. The capacitor Cst can supply a charged driving voltage to the driving transistor DT. The capacitor Cst can be a storage capacitor.

The compensation circuit CC can be provided to compensate for a threshold voltage of the driving transistor DT. The compensation circuit CC can be configured with one or more transistors. The compensation circuit CC can include one or more transistors and a capacitor and can be variously configured according to a compensation method. A pixel including the compensation circuit CC can have various structures such as 3T1C, 4T2C, 5T2C, 6T1C, 6T2C, 7T1C, and 7T2C.

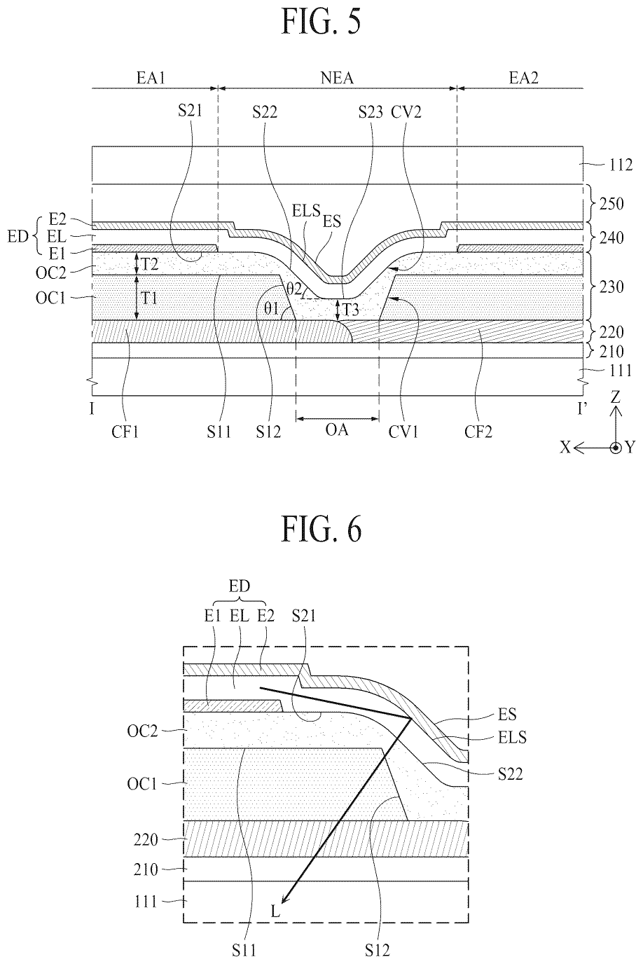

The display apparatus 100 according to an embodiment of the present disclosure can have a bottom emission structure where light emitted from the light emitting device ED is irradiated downward. In the display apparatus 100 according to an embodiment of the present disclosure, a structure of layers provided under the light emitting device ED can be modified, and thus, the extraction efficiency of the light emitted from the light emitting device E can be enhanced. Hereinafter, a structure for enhancing light extraction efficiency will be described in more detail with reference to FIGS. 5 to 10.

FIG. 5 is a cross-sectional view illustrating an embodiment of a subpixel taken along line I-I′ illustrated in FIG. 3 according to an embodiment of the present disclosure, and FIG. 6 is a cross-sectional view illustrating an example of a light path according to an embodiment of the present disclosure.

Referring to FIG. 5, a display panel 110 according to an embodiment of the present disclosure can include a first substrate 111 and a second substrate 112, which face each other, and a circuit element layer 210, a color filter layer 220, an organic insulation layer 230, a light emitting device layer 240, and an encapsulation layer 250 each provided between the first substrate 111 and the second substrate 112.

In the circuit element layer 210, a circuit element including various signal lines, a thin film transistor (TFT), and a capacitor can be provided for each of the subpixels SP1 to SP3. The signal lines can include scan lines, data lines, and power lines, and the TFT can include a switching transistor and a driving transistor. Also, the circuit element layer 210 can further include a plurality of insulation layers which are stacked on the first substrate 111.

The color filter layer 220 can be provided on the circuit element layer 210. The color filter layer 220 can be patterned and formed for each of the subpixels SP1 to SP3. In detail, the color filter layer 220 can include a first color filter CF1, a second color filter CF2, and a third color filter CF. The first color filter CF1 can be disposed to correspond to an emission region EA1 of the first subpixel SP1, and for example, can be a red color filter which transmits red light. The second color filter CF2 can be disposed to correspond to an emission region EA2 of the second subpixel SP2, and for example, can be a green color filter which transmits green light. The third color filter can be disposed to correspond to an emission region of the third subpixel SP3, and for example, can be a blue color filter which transmits blue light. When a pixel further includes a fourth subpixel, the color filter layer 220 can further include a fourth color filter. The fourth color filter can be disposed to correspond to an emission region of the fourth subpixel, and for example, can be a white color filter which transmits white light. The white color filter can include a transparent organic material which transmits white light, but embodiments of the present disclosure are not limited thereto. The white color filter can be omitted.

The first and second color filters CF1 and CF2 and the third color filter, as illustrated in FIG. 5, can at least partially overlap with each other in a region between the subpixels SP1 to SP3, but embodiments of the present disclosure are not limited thereto. The first and second color filters CF1 and CF2 and the third color filter can be disposed apart from one another in the region between the subpixels SP1 to SP3. According to an embodiment, all three of the first, second and third color filters CF1, CF2 and CF3 can overlap with each other in areas between adjacent subpixels to act as a black matrix and prevent light mixing, but embodiments are not limited thereto.

The organic insulation layer 230 can be provided on the color filter layer 220. The organic insulation layer 230 can include two or more organic insulation layers having different refractive indexes to enhance the extraction efficiency of light emitted from the light emitting device ED. The organic insulation layer 230 can include a first organic insulation layer OC1 and a second organic insulation layer OC2.

The first organic insulation layer OC1 can be provided on the color filter layer 220 and can have a first refractive index. The second organic insulation layer OC2 can be provided on the first organic insulation layer OC1 and can have a second refractive index. For example, the second refractive index can be greater than the first refractive index.

The second organic insulation layer OC2 can have a refractive index which is greater than that of the first organic insulation layer OC1, and thus, light emitted from the light emitting device ED can be refracted or reflected by an interface between the second organic insulation layer OC2 and the first organic insulation layer OC1, whereby a light path can be changed. The light extraction efficiency of the display panel 110 according to an embodiment of the present disclosure can be enhanced by a changed light path.

Moreover, the first organic insulation layer OC1 and the second organic insulation layer OC2 can each include a slope surface in a region between the subpixels SP1 to SP3. For example, one or more of the first organic insulation layer OC1 and the second organic insulation layer OC2 can have a sloped surface in an area between adjacent subpixels.

In detail, the first organic insulation layer OC1 can include a first flat surface S11 which is formed in a region overlapping each of the subpixels SP1 to SP3 and a first concave portion CV1 which is concavely formed in a region between the subpixels SP1 to SP3 to face the first substrate 111. For example, the first concave portion CV1 can be a type of channel or ditch between adjacent subpixels, but embodiments are not limited thereto. Also, the first concave portion CV1 can extend around one or more sides of each of the subpixels SP1 to SP3. The first concave portion CV1 of the first organic insulation layer OC1, as illustrated in FIG. 5, can include an opening region OA which exposes at least a portion of each of the color filters CF1 and CF2. For example, the opening region OA can extend or penetrate all the way through the first organic insulation layer OC1, but embodiments are not limited thereto. In this situation, the first concave portion CV1 of the first organic insulation layer OC1 can include a slope surface S12 (hereinafter referred to as a first slope surface) which is formed in at least one side of the opening region OA. The first slope surface S12 can have a first slope θ1 which is high or steep. In an embodiment, the first slope θ1 can be 70 degrees or more.

The first slope surface S12 can have the first slope θ1 which is high, and thus, the first organic insulation layer OC1 can have a first thickness T1 which is relatively thick. For example, the first organic insulation layer OC1 can be thicker than the second organic insulation layer OC2, but embodiments are not limited there to. According to another embodiment, the second organic insulation layer OC2 can be thicker than the first organic insulation layer OC1 or the first and second organic insulation layers OC1 and OC2 can have a same thickness. Also, the slopes of each organic insulation layers can be adjusted by changing a width of the opening region OA. The first organic insulation layer OC1 can include an organic material. The organic material can be changed in thickness and flatness, based on viscosity. The first organic insulation layer OC1 can include an organic material having a first viscosity which is high. For example, the first organic insulation layer OC1 can include photoacryl (PAC). Comparing with the second organic insulation layer OC2, the first organic insulation layer OC1 can have the first thickness T1 which is thick, and a surface of the first organic insulation layer OC1 can be uniformly planarized (e.g., T1 can be greater than T2).

In the display panel 110 according to an embodiment of the present disclosure, the first slope surface S12 of the first organic insulation layer OC1 can have the first slope θ1 which is high or steep, and thus, a separation distance between the subpixels SP1 to SP3 can decrease. For example, by making the first slope θ1 steep, the subpixels SP1 to SP3 can be spaced closer together, which can increase subpixel density and improve resolution.

The second organic insulation layer OC2 can include a first flat surface S21 which is formed in a region overlapping with each of the subpixels SP1 to SP3 and a second concave portion CV2 which is concavely formed in a region between the subpixels SP1 to SP3 to face the first substrate 111. The second concave portion CV2 can be disposed to correspond to the first concave portion CV1 of the first organic insulation layer OC1. At least a portion of the second concave portion CV2 of the second organic insulation layer OC2 can overlap with the first concave portion CV1 of the first organic insulation layer OC1.

The second concave portion CV2 of the second organic insulation layer OC2, as illustrated in FIG. 5, can be formed to cover or overlap with portions color filters CF1 and CF2 that are exposed by the opening region OA of the first organic insulation layer OC1. In this situation, the second concave portion CV2 of the second organic insulation layer OC2 can include a second flat surface S23 and a slope surface S22 (hereinafter referred to as a second slope surface) each provided at a height which is lower than the first flat surface S21. The second slope surface S22 can be disposed in at least one side of the second flat surface S23 and can be a surface which connects the first flat surface S21 to the second flat surface S23. At least a portion of the second slope surface S22 can overlap with the first slope surface S12 of the first organic insulation layer OC1. In FIG. 5, it is illustrated that the second flat surface S23 is formed at the second concave portion CV2, but embodiments of the present disclosure are not limited thereto. In the second concave portion CV2 of the second organic insulation layer OC2, the second flat surface S23 can be omitted based on a separation distance between the subpixels SP1 to SP3 or the viscosity of an organic material of the second organic insulation layer OC2. Alternatively, in the second concave portion CV2 of the second organic insulation layer OC2, the second flat surface S23 may not be a flat surface (e.g., it may be textured, wavy, etc. and can correspond to a lowermost area of the second concave portion CV2).

The second slope surface S22 of the second organic insulation layer OC2 can have a second slope θ2 which is less steep or more gentle than the first slope surface S12 of the second organic insulation layer OC1 (e.g., S12>S22). In an embodiment, the second slope θ2 can be 45 degrees or less.

The second slope surface S22 can have the second slope θ2, and thus, the second organic insulation layer OC2 can have a second thickness T2 which is relatively thin (e.g., T2<T1). When the second thickness T2 of the second organic insulation layer OC2 is made too thick, a horizontal distance of the second slope surface S22 of the second organic insulation layer OC2 can increase when the second slope θ2 is formed to be 45 degrees or less. Also, the steepness of the second slope θ2 can be adjusted based on the thickness of second organic insulation layer OC2 and/or the width of the opening region OA of the first organic insulation layer OC1. As the horizontal distance of the second slope surface S22 of the second organic insulation layer OC2 increases, the separation distance between the subpixels SP1 to SP3 can increase. Accordingly, the display panel 110 may decrease in aperture ratio, which may impair or lower image resolution. In the display panel 110 according to an embodiment of the present disclosure, the second thickness T2 of the second organic insulation layer OC2 can be formed to be thin, and thus, the second slope θ2 of the second slope surface S22 of the second organic insulation layer OC2 can still be formed to be 45 degrees or less and the separation distance between the subpixels SP1 to SP3 may not increase, which can increase subpixel density and provide higher resolution.

The second organic insulation layer OC2 can include an organic material. The thickness and planarization characteristic of an organic material can be changed based on viscosity. The second organic insulation layer OC2 can include an organic material having a second viscosity which is low, e.g., lower than a viscosity of the first organic insulation layer OC1. For example, the second organic insulation layer OC2 can include polyimide (PI) or siloxane-group organic material. The second organic insulation layer OC2 can have the second thickness T2 which is thin compared to the first organic insulation layer OC1 and can allow planarization not to be implemented in the second concave portion CV2. Accordingly, the second organic insulation layer OC2 can sufficiently secure an area of the second slope surface S22 in the second concave portion CV2.

The second organic insulation layer OC2 (or the second concave portion CV2) can be formed to cover the color filters CF1 and CF2 exposed by the opening region OA of the first organic insulation layer OC1. Accordingly, the second organic insulation layer OC2 can prevent a gas outgassed from the color filters CF1 and CF2 from moving to the light emitting device ED, which can help prevent image defects and increase a life span of the device.

The light emitting device layer 240 can be disposed on the organic insulation layer 230. The light emitting device layer 240 can include light emitting devices ED respectively included in the subpixels SP1 to SP3. Each of the light emitting devices ED can include a first electrode E1, an emission layer EL, and a second electrode E2.

The first electrode E1 can be provided on the organic insulation layer 230. In detail, the first electrode E1 can be provided on the first flat surface S21 of the second organic insulation layer OC2, for each of the subpixels SP1 to SP3. Also, the first electrode E1 can be connected to the driving transistor DT (see FIG. 4). In detail, the first electrode E1 can be connected to one of a source electrode and a drain electrode of the driving transistor DT (see FIG. 4) through a contact hole which passes through at least a portion of each of the organic insulation layer 230 and a plurality of insulation layers included in the circuit element layer 210.

An edge of at least one side of the first electrode E1 can be the same as an edge of each of emission regions EA1 and EA2. In the display panel 110 according to an embodiment of the present disclosure, a separate bank may not be formed on the first electrode E1, in this way, the device can be made thinner and the number of processing steps can be reduced. Therefore, an entire region of the first electrode E1 can be formed to contact the emission layer EL, and light can be emitted from the emission layer EL. A bank may not be formed in an edge region of the first electrode E1 and the first electrode E1 can contact the emission layer EL, and thus, the edge of the at least one side of the first electrode E1 can be the same as the edge of each of emission regions EA1 and EA2. An edge, facing the second subpixel SP2, of a first electrode E1 included in the first subpixel SP1, as illustrated in FIG. 5, can be the same as an edge of a first emission region EA1, and an edge, facing the first subpixel SP1, of a first electrode E1 included in the second subpixel SP2 can be the same as an edge of a second emission region EA2. A non-emission region NEA can be between an end of the first electrode E1 included in the first subpixel SP1 and the first electrode E1 included in the second subpixel SP2. In the display panel 110 according to an embodiment of the present disclosure, because a separate bank is not formed on the first electrode E1, an area of the emission regions EA1 and EA2 can increase, and an aperture ratio can be enhanced and a higher resolution can be implemented. For example, since a bank on the edge of the first electrode E1 can be avoided or omitted, the subpixels can be packed more closely together.

The first electrode E1 can include a transparent conductive material (TCO) such as indium tin oxide (ITO) or indium zinc oxide (IZO) capable of transmitting light. The first electrode E1 can include a semi-transmissive conductive material such as magnesium (Mg), silver (Ag), or an alloy of Mg and Ag and can have a thin thickness which enables the transmission of light. When the first electrode E1 includes a semi-transmissive conductive material, the light output efficiency of the first electrode E1 can be increased by a micro cavity. The first electrode E1 can be an anode electrode of the light emitting device ED.

The emission layer EL can be disposed on the first electrode E1. The emission layer EL can include an emission material layer (EML) including an emission material. The emission material can include an organic material, inorganic material, or a hybrid material. The emission layer EL can have a multi-layer structure. For example, the emission layer EL can further include a hole injection layer (HIL), a hole transport layer (HTL), an electron transport layer (ETL), and an electron injection layer (EIL). In this situation, when a voltage is applied to the first electrode E1 and the second electrode E2, a hole and an electron can move to the emission material layer through the hole transport layer and the electron transport layer and can be combined in the emission material layer to emit light.

In an embodiment, the emission layer EL can be a common layer which is formed in the subpixels SP1 to SP3 in common. In this situation, the emission layer EL can be a white emission layer which emits white light. Also, the emission layer EL can be formed in a region between the subpixels SP1 to SP3, in addition to the subpixels SP1 to SP3. The emission layer EL can be continuously formed in the subpixels SP1 to SP3 and between the subpixels SP1 to SP3. In other words, emission layer EL can be laid across the subpixels as a common sheet layer. The emission layer EL can be formed on the second concave portion CV2 of the second organic insulation layer OC2, between the subpixels SP1 to SP3, and can be formed along the second slope surface S22. A slope surface ELS (hereinafter referred to as a third slope surface) which at least partially overlaps the second slope surface S22 of the second organic insulation layer OC2 can be formed in the emission layer EL. For example, a slope of the third slope surface ELS can be equal to the second slope surface S22.

In another embodiment, the emission layer EL can be discretely or independently formed for each of the subpixels SP1 to SP3. For example, a red emission layer emitting red light can be formed in the first subpixel SP1, a green emission layer emitting green light can be formed in the second subpixel SP2, and a blue emission layer emitting blue light can be formed in the third subpixel SP3.

The second electrode E2 can be disposed on the emission layer EL. The second electrode E2 can be a common layer which is formed in the subpixels SP1 to SP3 in common. The second electrode E2 can be formed in a region between the subpixels SP1 to SP3, in addition to the subpixels SP1 to SP3. The second electrode E2 can be continuously formed in the subpixels SP1 to SP3 and between the subpixels SP1 to SP3. The second electrode E2 can be formed on the second concave portion CV2 of the second organic insulation layer OC2, between the subpixels SP1 to SP3, and can be formed along the second slope surface S22. In other words, second electrode E2 can be laid across the subpixels as a common sheet layer. In a situation where the emission layer EL is provided as a common layer, as illustrated in FIG. 5, the second electrode E2 can be formed on a third slope surface ELS of the emission layer EL along the third slope surface ELS. A slope surface ES (hereinafter referred to as a fourth slope surface) which at least partially overlaps the second slope surface S22 of the second organic insulation layer OC2 can be formed in the second electrode E2. For example, the fourth slope surface ES can be equal to both of the slope of the third slope surface ELS and the second slope surface S22.

The second electrode E2 can include a conductive material having a high reflectance. The second electrode E2 can include metal such as aluminum (Al), silver (Ag), titanium (Ti), or a silver-palladium-copper (APC) alloy. The second electrode E2 can be a cathode electrode.

The display panel 110 according to an embodiment of the present disclosure can include the first concave portion CV1 of the first organic insulation layer OC1 and the second concave portion CV2 of the second organic insulation layer OC2, and thus, the fourth slope surface ES can be formed in the second electrode E2. In the display panel 110 according to an embodiment of the present disclosure, as illustrated in FIG. 6, when light L emitted from the light emitting device ED moves to a lateral surface, the light L can be reflected by the fourth slope surface ES (or the third slope surface ELS) included in the second electrode E2 (or in the emission layer EL), and thus, a path of the light L can be changed to a downward directed or a forward direction toward a viewer or user. For example, a cross section of the second electrode can have a “V” shape in a non-emission area between the first subpixel and the second subpixel to reflect light emitted from the first emission area EA1 or the second emission area EA2 in a downward direction toward the first substrate (e.g., a forward direction to a user). Here, the forward direction can represent a direction toward the first substrate 111. Accordingly, the display panel 110 according to an embodiment of the present disclosure can enhance light extraction efficiency and can prevent the occurrence of color mixture between adjacent subpixels SP1 to SP3, while also allowing the display device to be much thinner and pack subpixels closer together, and can reduce the number of manufacturing steps.

The encapsulation layer 250 can be disposed on the light emitting device layer 240. The encapsulation layer 250 can prevent the light emitting devices ED from being damaged by external water penetration and external impacts. The encapsulation layer 250 can have a multi-layer structure. For example, the encapsulation layer 250 can include at least one inorganic layer and at least one organic layer.

In the display panel 110 according to an embodiment of the present disclosure, the second organic insulation layer OC2 can have a refractive index which is greater than a refractive index of the first organic insulation layer OC1, and thus, light emitted from the light emitting device ED can be refracted or reflected by an interface between the second organic insulation layer OC2 and the first organic insulation layer OC1, whereby a light path can be changed. The light extraction efficiency of the display panel 110 according to an embodiment of the present disclosure can be enhanced by a changed light path.

Moreover, in the display panel 110 according to an embodiment of the present disclosure, the first organic insulation layer OC1 can have the first thickness T1 which is thick (e.g., T1>T2), and thus, step heights occurring in the circuit element layer 210 and the color filter layer 220 can be planarized.

Moreover, in the display panel 110 according to an embodiment of the present disclosure, the first organic insulation layer OC1 can include the first concave portion CV1 including the first slope surface S12 in a region between the subpixels SP1 to SP3. Accordingly, in the display panel 110 according to an embodiment of the present disclosure, the slope surfaces S22, ELS, and ES can be respectively formed in the second organic insulation layer OC2, the emission layer EL, and the second electrode E2, which are sequentially stacked on the first slope surface S12 of the first organic insulation layer OC1. Also, the second concave portion CV2 can overlap with and be wider than the first concave portion CV1.

Particularly, in the display panel 110 according to an embodiment of the present disclosure, the second electrode E2 which is a reflection electrode can include the slope surface ES which is inclined toward the first substrate 111 and is provided in a region between the subpixels SP1 to SP3, thereby enhancing light extraction efficiency. In the display panel 110 according to an embodiment of the present disclosure, the light L which is emitted from the light emitting device ED and moves to a lateral surface can be reflected by the slope surface ES of the second electrode E2, and thus, a path of the light L can be changed to a forward or downward direction. Therefore, the display panel 110 according to an embodiment of the present disclosure can enhance light extraction efficiency and can prevent the occurrence of color mixture between adjacent subpixels SP1 to SP3, while also allowing the display device to be much thinner and pack subpixels closer together, and can reduce the number of manufacturing steps.

Moreover, in the display panel 110 according to an embodiment of the present disclosure, the thickness T1 of the first organic insulation layer OC1 can be formed to be thick (e.g., T1>T2), and thus, a depth (or a vertical distance) of the first concave portion CV1 can be formed to be deep. Accordingly, an area of the first slope surface S12 of the first concave portion CV1 can increase. In the display panel 110 according to an embodiment of the present disclosure, an area of each of the second, third and fourth slope surfaces S22, ELS, and ES of the second organic insulation layer OC2, the emission layer EL, and the second electrode E2 sequentially stacked on the first slope surface S12 of the first concave portion CV1 can increase. As a result, in the display panel 110 according to an embodiment of the present disclosure, the slope surface ES of the second electrode E2 can have a very wide area, and thus, an area enabling light to be incident can increase, thereby increasing light extraction efficiency. The display panel 110 according to an embodiment of the present disclosure can have high light extraction efficiency with low power, and moreover, can decrease power consumption. Also, the display panel 110 according to an embodiment of the present disclosure can pack subpixels closer together to increase resolution, be made much thinner since a bank and other portions can be omitted, and can reduce the number manufacturing steps which improves efficiency and reduces costs.

Moreover, in the display panel 110 according to an embodiment of the present disclosure, the first slope surface S12 of the first organic insulation layer OC1 can have the first slope θ1 which is high or steep (e.g., first slope θ1>second slope θ2), and thus, a separation distance between the subpixels SP1 to SP3 can decrease and the subpixels can be spaced closer together. In the display panel 110 according to an embodiment of the present disclosure, an area of the non-emission region NEA can be reduced, and an aperture ratio can be enhanced and a higher resolution can be provided.

Moreover, in the display panel 110 according to an embodiment of the present disclosure, the second slope surface S22 of the second organic insulation layer OC2 can have the second slope θ2 which is lower than or more gentle than the first slope surface S12 of the first organic insulation layer OC1. The emission layer EL and the second electrode E2 can be formed on the second slope surface S22 of the second organic insulation layer OC2. The emission layer EL can include an organic material and can be formed to have a uniform thickness on the second organic insulation layer OC2. That is, a large difference between a thickness of the emission layer EL on the first flat surface S21 of the second organic insulation layer OC2 and a thickness of the emission layer EL on the second slope surface S22 of the second organic insulation layer OC2 may not occur.

On the other hand, the second electrode E2 can include a reflective metal material, and a step coverage may not be good. A thickness of the second electrode E2 on the second slope surface S22 of the second organic insulation layer OC2 can be formed to be thinner than a thickness of the second electrode E2 on the first flat surface S21 of the second organic insulation layer OC2.

As a slope of the second slope surface S22 of the second organic insulation layer OC2 increases to become too steep, a thickness of the second electrode E2 deposited on the second slope surface S22 of the second organic insulation layer OC2 may be formed to be thin. In the second electrode E2, as a thickness is thinned on the second slope surface S22 of the second organic insulation layer OC2, a region where the second electrode E2 is not deposited can occur, or a crack can occur. In this situation, the second electrode E2 may not completely cover the emission layer EL, and due to this, water or oxygen can penetrate into the emission layer EL, causing a degradation in the light emitting device ED.

In the display panel 110 according to an embodiment of the present disclosure, the second slope surface S22 of the second organic insulation layer OC2 can have the second slope θ2 which is low or much more gentle, and thus, the second electrode E2 can be securely and uniformly deposited on the second slope surface S22 of the second organic insulation layer OC2 to have a certain thickness or more. In the display panel 110 according to an embodiment of the present disclosure, since the second slope surface S22 is made to be more gentle or less steep, the second electrode E2 can be thinly and uniformly formed on the second slope surface S22 of the second organic insulation layer OC2 without any gaps or cracks, and thus, can prevent the light emitting device ED from being degraded.

Furthermore, in the display panel 110 according to an embodiment of the present disclosure, the thickness T2 of the second organic insulation layer OC2 can be formed to be thin, and thus, even when the second slope surface S22 of the second organic insulation layer OC2 has the second slope θ2 which is low, the separation distance between the subpixels SP1 to SP3 may not increase. Also, in the display panel 110 according to an embodiment of the present disclosure, a total thickness of the first organic insulation layer OC1 and the second organic insulation layer OC2 can decrease and can thus prevent the occurrence of a light leakage phenomenon where light emitted from the light emitting device ED is leaked to adjacent subpixels SP1 to SP3. Thus, a thinner device can be provided, which also has improved brightness and reduced power consumption.

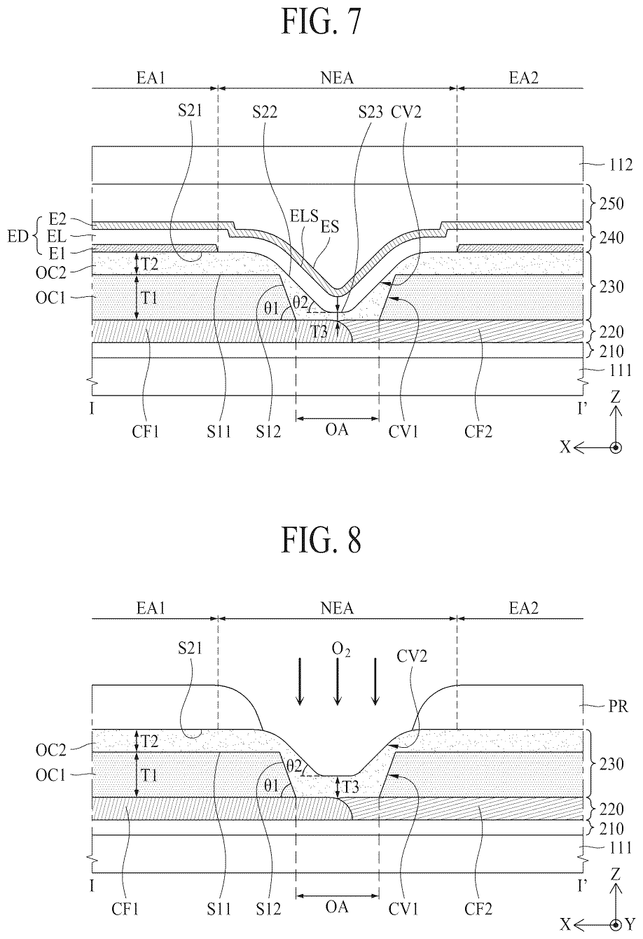

FIG. 7 is a cross-sectional view illustrating another embodiment of a subpixel taken along line I-I′ illustrated in FIG. 3, and FIG. 8 is a cross-sectional view illustrating an example of an ashing process on a second organic insulation layer.

Except for only an organic insulation layer OC, the other elements of a display panel 110 illustrated in FIG. 7 can be substantially the same as the display panel 110 illustrated in FIG. 5, and thus, their detailed descriptions are omitted.

Referring to FIG. 7, a display panel 110 according to another embodiment of the present disclosure can include a first substrate 111 and a second substrate 112, which face each other, and a circuit element layer 210, a color filter layer 220, an organic insulation layer 230, a light emitting device layer 240, and an encapsulation layer 250 each provided between the first substrate 111 and the second substrate 112.

The organic insulation layer 230 can be provided on the color filter layer 220. The organic insulation layer 230 can include two organic insulation layers having different refractive indexes to enhance the extraction efficiency of light emitted from the light emitting device ED. The organic insulation layer 230 can include a first organic insulation layer OC1 and a second organic insulation layer OC2.

The first organic insulation layer OC1 can be provided on the color filter layer 220 and can have a first refractive index. The second organic insulation layer OC2 can be provided on the first organic insulation layer OC1 and can have a second refractive index. For example, the second refractive index can be greater than the first refractive index.

The second organic insulation layer OC2 can have a refractive index which is greater than a refractive index of the first organic insulation layer OC1, and thus, light emitted from the light emitting device ED can be refracted or reflected by an interface between the second organic insulation layer OC2 and the first organic insulation layer OC1, whereby a light path can be changed. The light extraction efficiency of the display panel 110 according to an embodiment of the present disclosure can be enhanced by a changed light path.

Moreover, the first organic insulation layer OC1 and the second organic insulation layer OC2 can each include a slope surface in a region between the subpixels SP1 to SP3.

In detail, the first organic insulation layer OC1 can include a first flat surface S11 which is formed in a region overlapping with each of the subpixels SP1 to SP3 and a first concave portion CV1 which is concavely formed in a region between the subpixels SP1 to SP3 to face the first substrate 111. The first concave portion CV1 of the first organic insulation layer OC1, as illustrated in FIG. 7, can include an opening region OA which exposes at least a portion of each of the color filters CF1 and CF2. In this situation, the first concave portion CV1 of the first organic insulation layer OC1 can include a first slope surface S12 which is formed in at least one side of the opening region OA. The first slope surface S12 can have a first slope θ1 which is high. In an embodiment, the first slope θ1 can be 70 degrees or more.

The first slope surface S12 can have the first slope θ1 which is high or steep, and thus, the first organic insulation layer OC1 can have a first thickness T1 which is relatively thick (e.g., T1>T2). The first organic insulation layer OC1 can include an organic material. The organic material can be changed in thickness and flatness, based on viscosity. The first organic insulation layer OC1 can include an organic material having a first viscosity which is high. For example, the first organic insulation layer OC1 can include photoacryl (PAC). Comparing with the second organic insulation layer OC2, the first organic insulation layer OC1 can have the first thickness T1 which is thick, and a surface of the first organic insulation layer OC1 can be uniformly planarized.

In the display panel 110 according to another embodiment of the present disclosure, the first slope surface S12 of the first organic insulation layer OC1 can have the first slope θ1 which is high or steep, and thus, a separation distance between the subpixels SP1 to SP3 can decrease. In this way, more subpixels can be packed closer together and a higher resolution can be provided.

The second organic insulation layer OC2 can include a first flat surface S21 which is formed in a region overlapping with each of the subpixels SP1 to SP3 and a second concave portion CV2 which is concavely formed in a region between the subpixels SP1 to SP3 to face the first substrate 111. At least a portion of the second concave portion CV2 of the second organic insulation layer OC2 can overlap the first concave portion CV1 of the first organic insulation layer OC1. For example, a center or lowermost point of the second concave portion CV2 of the second organic insulation layer OC2 can overlap with a center or lowermost point of the first concave portion CV1 of the first organic insulation layer OC1, but embodiments are not limited thereto.

The second concave portion CV2 of the second organic insulation layer OC2, as illustrated in FIG. 7, can be formed to cover portions of the color filters CF1 and CF2 that are exposed by the opening region OA of the first organic insulation layer OC1. In this situation, the second concave portion CV2 of the second organic insulation layer OC2 can include a second flat surface S23 (e.g., lowermost surface) and a second slope surface S22 each provided at a height which is lower than the first flat surface S21. The second slope surface S22 can be disposed in at least one side of the second flat surface S23 and can be a surface which connects the first flat surface S21 to the second flat surface S23. At least a portion of the second slope surface S22 can overlap with the first slope surface S12 of the first organic insulation layer OC1. In FIG. 7, it is illustrated that the second flat surface S23 is formed at the second concave portion CV2, but embodiments of the present disclosure are not limited thereto. In the second concave portion CV2 of the second organic insulation layer OC2, the second flat surface S23 can be omitted based on a separation distance between the subpixels SP1 to SP3 or the viscosity of an organic material of the second organic insulation layer OC2. Alternatively, in the second concave portion CV2 of the second organic insulation layer OC2, the second flat surface S23 may not be a flat surface (e.g., it may be a point, a textured surface or wavy, etc.).

The second slope surface S22 of the second organic insulation layer OC2 can have a second slope θ2 which is lower or more gentle than the first slope surface S12 of the second organic insulation layer OC1. In an embodiment, the second slope θ2 can be 45 degrees or less (e.g., first slope θ1>second slope θ2).

The second slope surface S22 can have the second slope θ2 which is less steep, and thus, the second organic insulation layer OC2 can have a second thickness T2 which is relatively thin. When the second thickness T2 of the second organic insulation layer OC2 is thick, a horizontal distance of the second slope surface S22 of the second organic insulation layer OC2 can increase so that the second slope θ2 is formed to be 45 degrees or less. As the horizontal distance of the second slope surface S22 of the second organic insulation layer OC2 increases, the separation distance between the subpixels SP1 to SP3 can increase. Accordingly, the display panel 110 may decrease in aperture ratio. In the display panel 110 according to another embodiment of the present disclosure, the second thickness T2 of the second organic insulation layer OC2 can be formed to be thin, and thus, the second slope θ2 of the second slope surface S22 of the second organic insulation layer OC2 can be formed to be 45 degrees or less and the separation distance between the subpixels SP1 to SP3 may not increase and the subpixels can be disposed closer together.

The second organic insulation layer OC2 can include an organic material. The thickness and planarization characteristic of an organic material can be changed based on viscosity. The second organic insulation layer OC2 can include an organic material having a second viscosity which is low. For example, the second organic insulation layer OC2 can include polyimide (PI) or siloxane-group organic material. The second organic insulation layer OC2 can have the second thickness T2 which is thin compared to the first organic insulation layer OC1 and can allow planarization not to be implemented in the second concave portion CV2. Accordingly, the second organic insulation layer OC2 can sufficiently secure an area of the second slope surface S22 in the second concave portion CV2.

Furthermore, in the second organic insulation layer OC2 illustrated in FIG. 7, a third thickness T3 at the third flat surface S23 or a point at which second slope surfaces S22 provided to face each other contact each other can be less than the second thickness T2 at the first flat surface S21 (e.g., T3<T2<T1).

In detail, in the second organic insulation layer OC2 according to an embodiment of the present disclosure illustrated in FIG. 5, the first flat surface S21, the second slope surface S22, and the third flat surface S23 can be simultaneously formed. In the second organic insulation layer OC2, the second thickness T2 at the first flat surface S21 can be the same as the third thickness T3 at the third flat surface S23 or a point at which second slope surfaces S22 provided to face each other contact each other, or a difference therebetween can occur within a small range (e.g., in FIG. 5, T2 can be equal to or substantially equal to T3).

On the other hand, in the second organic insulation layer OC2 according to another embodiment of the present disclosure illustrated in FIG. 7, the first flat surface S21, the second slope surface S22, and the third flat surface S23 may not be simultaneously formed. First, the second organic insulation layer OC2 can be formed to have the second thickness T2 on the first flat surface S11 and the first slope surface S12 of the first organic insulation layer OC1. Subsequently, as illustrated in FIG. 8, a photoresist pattern PR can be formed on the first flat surface S21 of the second organic insulation layer OC2, and an ashing process can be performed by using a gas such as NF₃ or O₂. A portion of the second organic insulation layer OC2 can be removed in a region (i.e., a region between the subpixels SP1 to SP3) which is not covered by the photoresist pattern PR, based on the ashing process, and thus, a thickness of the second organic insulation layer OC2 can be reduced, whereby the second slope surface S22 and the third flat surface S23 can be formed. In other words, subsequent to forming the first flat surface S21, the second concave portion CV2 of the second organic insulation layer OC2 can be etch deeper so that the second slope surface S22 and the third flat surface S23 are further changed. Accordingly, in the second organic insulation layer OC2, the third thickness T3 at the third flat surface S23 or a point at which second slope surfaces S22 provided to face each other contact each other can be less than the second thickness T2 at the first flat surface S21 (e.g., in FIG. 7, T3<T2). In this situation, the third thickness T3 at the third flat surface S23 or a point at which second slope surfaces S22 provided to face each other contact each other can have a minimum thickness which enables the color filters CF1 and CF2 to be covered.

In the display panel 110 according to another embodiment of the present disclosure, the second concave portion CV2 of the second organic insulation layer OC2 can have a maximum depth (or a vertical distance) through the ashing process, and thus, the second slope surface S22 of the second concave portion CV2 can have a maximum area which can reflect even more light. Accordingly, in the display panel 110 according to another embodiment of the present disclosure, the slope surface ES of the second electrode E2 can have a maximum area, and light extraction efficiency can be further maximized.

The second organic insulation layer OC2 (or the second concave portion CV2) can be formed to cover the color filters CF1 and CF2 exposed by the opening region OA of the first organic insulation layer OC1. Accordingly, the second organic insulation layer OC2 can prevent a gas outgassed from the color filters CF1 and CF2 from moving to the light emitting device ED.

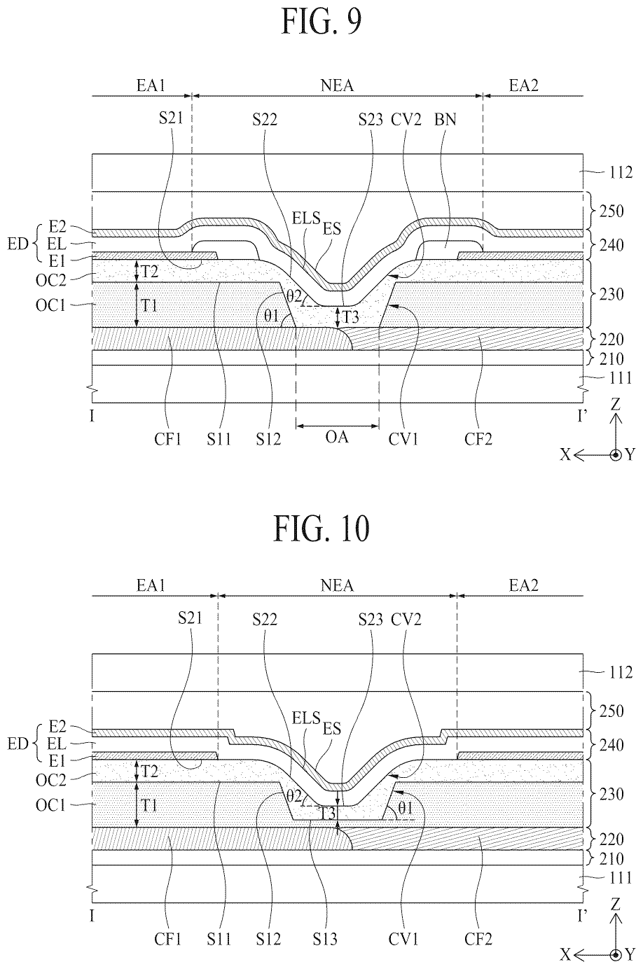

FIG. 9 is a cross-sectional view illustrating another embodiment of a subpixel taken along line I-I′ illustrated in FIG. 3.

Except for that a display panel 110 illustrated in FIG. 9 further includes a bank BN, the other elements of the display panel 110 illustrated in FIG. 9 can be substantially the same as the display panel 110 illustrated in FIG. 5, and thus, their detailed descriptions are omitted.

Referring to FIG. 9, a display panel 110 according to another embodiment of the present disclosure can include a first substrate 111 and a second substrate 112, which face each other, and a circuit element layer 210, a color filter layer 220, an organic insulation layer 230, a light emitting device layer 240, and an encapsulation layer 250 each provided between the first substrate 111 and the second substrate 112.

The light emitting device layer 240 can be disposed on the organic insulation layer 230. The light emitting device layer 240 can include a bank BN and light emitting devices ED respectively included in the subpixels SP1 to SP3. Each of the light emitting devices ED can include a first electrode E1, an emission layer EL, and a second electrode E2.

The bank BN can cover or overlap with an edge of the first electrode E1 included in each of the subpixels SP1 to SP3. The bank BN may not overlap a first concave portion CV1 of a first organic insulation layer OC1 and a second concave portion CV2 of a second organic insulation layer OC2. Banks BN may not be connected to each other in a region between the subpixels SP1 to SP3. For example, a bank BN formed to cover an edge of a first electrode E1 of the first subpixel SP1 can be disposed apart from a bank BN, formed to cover an edge of a first electrode E1 of the second subpixel SP2, with the first concave portion CV1 of the first organic insulation layer OC1 and the second concave portion CV2 of the second organic insulation layer OC2 therebetween. The bank BN can include an opening portion through which the first electrode E1 is exposed and can define a first emission region EA1 and a second emission region EA2. A region where the bank BN is provided can be included in a non-emission region NEA.

The emission layer EL of the light emitting device ED can be continuously formed between subpixels SP1 to SP3 and subpixels SP1 to SP3. The emission layer EL can be formed on the first electrode E1 exposed by the opening portion of the bank BN, in each of the subpixels SP1 to SP3. Also, the emission layer EL can be formed on the bank BN and the second concave portion CV2 of the second organic insulation layer OC2, between the subpixels SP1 to SP3. In this situation, the emission layer EL can be formed along one side of the bank BN and the second slope surface S22 of the second organic insulation layer OC2, and a third slope surface ELS can be formed in the emission layer EL.

The second electrode E2 of the light emitting device ED can be formed in a region between the subpixels SP1 to SP3, in addition to the subpixels SP1 to SP3. The second electrode E2 can be continuously formed in the subpixels SP1 to SP3 and between the subpixels SP1 to SP3. The second electrode E2 can be formed on the first electrode E1 exposed by an opening portion of the bank BN in each of the subpixels SP1 to SP3. Also, the second electrode E2 can be formed on the bank BN and the second concave portion CV2 of the second organic insulation layer OC2, between the subpixels SP1 to SP3. In this situation, the second electrode E2 can be formed along one side of the bank BN and the second slope surface S22 of the second organic insulation layer OC2, and a fourth slope surface ES can be formed in the second electrode E2.

In the display panel 110 according to another embodiment of the present disclosure, the second electrode E2 can be formed along one side of the bank BN as well as the second slope surface S22 of the second organic insulation layer OC2, and thus, an area of the fourth slope surface ES can increase, in order capture and reflect even more light. In the display panel 110 according to another embodiment of the present disclosure, an area of the fourth slope surface ES of the second electrode E2 can increase, and thus, an area enabling light to be incident can increase, thereby increasing light extraction efficiency.

FIG. 10 is a cross-sectional view illustrating another embodiment of a subpixel taken along line I-I′ illustrated in FIG. 3.

Except for only an organic insulation layer OC, the other elements of a display panel 110 illustrated in FIG. 10 can be substantially the same as the display panel 110 illustrated in FIG. 5, and thus, their detailed descriptions are omitted.

Referring to FIG. 10, a display panel 110 according to another embodiment of the present disclosure can include a first substrate 111 and a second substrate 112, which face each other, and a circuit element layer 210, a color filter layer 220, an organic insulation layer 230, a light emitting device layer 240, and an encapsulation layer 250 each provided between the first substrate 111 and the second substrate 112.

The organic insulation layer 230 can be provided on the color filter layer 220. The organic insulation layer 230 can include two organic insulation layers having different refractive indexes to enhance the extraction efficiency of light emitted from the light emitting device ED. The organic insulation layer 230 can include a first organic insulation layer OC1 and a second organic insulation layer OC2.

The first organic insulation layer OC1 can be provided on the color filter layer 220 and can have a first refractive index. The second organic insulation layer OC2 can be provided on the first organic insulation layer OC1 and can have a second refractive index. For example, the second refractive index can be greater than the first refractive index.

The second organic insulation layer OC2 can have a refractive index which is greater than that of the first organic insulation layer OC1, and thus, light emitted from the light emitting device ED can be refracted or reflected by an interface between the second organic insulation layer OC2 and the first organic insulation layer OC1, whereby a light path can be changed. The light extraction efficiency of the display panel 110 according to another embodiment of the present disclosure can be enhanced by a changed light path.

Moreover, the first organic insulation layer OC1 and the second organic insulation layer OC2 can each include a slope surface in a region between the subpixels SP1 to SP3.

In detail, the first organic insulation layer OC1 can include a first flat surface S11 which is formed in a region overlapping with each of the subpixels SP1 to SP3 and a first concave portion CV1 which is concavely formed in a region between the subpixels SP1 to SP3 to face the first substrate 111. The first concave portion CV1 of the first organic insulation layer OC1, as illustrated in FIG. 10, can be formed to cover the color filters CF1 and CF2. The first concave portion CV1 of the first organic insulation layer OC1 can include a second flat surface S13 and a second slope surface S12 each provided at a height which is lower than the first flat surface S11. In other words, the first organic insulation layer OC1 can be laid continuously across adjacent subpixels so that the color filters are covered by both of the first organic insulation layer OC1 and the second organic insulation layer OC2 which can better protect the subpixels from any outgassing (e.g., a thin portion of first organic insulation layer OC1 can extend across the area between adjacent subpixels). The first slope surface S12 can be disposed in at least one side of the second flat surface S13 and can be a surface which connects the first flat surface S11 to the second flat surface S13. In FIG. 10, it is illustrated that the second flat surface S13 is formed at the first concave portion CV1, but embodiments of the present disclosure are not limited thereto. In the first concave portion CV1 of the first organic insulation layer OC1, the second flat surface S13 can be omitted based on a separation distance between the subpixels SP1 to SP3 or the viscosity of an organic material of the first organic insulation layer OC1. Alternatively, in the first concave portion CV1 of the first organic insulation layer OC1, the second flat surface S13 may not be a flat surface (e.g., it may be a pointed depression, a textured surface or a wavy or curvy surface, etc.).

The first slope surface S12 can have a first slope θ1 which is high or steep. In an embodiment, the first slope θ1 can be 70 degrees or more.

The first slope surface S12 can have the first slope θ1 which is high, and thus, the first organic insulation layer OC1 can have a first thickness T1 which is relatively thick. The first organic insulation layer OC1 can include an organic material. The organic material can be changed in thickness and flatness, based on viscosity. The first organic insulation layer OC1 can include an organic material having a first viscosity which is high. For example, the first organic insulation layer OC1 can include photoacryl (PAC). Comparing with the second organic insulation layer OC2, the first organic insulation layer OC1 can have the first thickness T1 which is thick, and a surface of the first organic insulation layer OC1 can be uniformly planarized.

In the display panel 110 according to another embodiment of the present disclosure, the first slope surface S12 of the first organic insulation layer OC1 can have the first slope θ1 which is high, and thus, a separation distance between the subpixels SP1 to SP3 can decrease and subpixels can be spaced closer together.

The second organic insulation layer OC2 can include a first flat surface S21 which is formed in a region overlapping with each of the subpixels SP1 to SP3 and a second concave portion CV2 which is concavely formed in a region between the subpixels SP1 to SP3 to face the first substrate 111.

At least a portion of the second concave portion CV2 of the second organic insulation layer OC2, as illustrated in FIG. 10, can overlap with the first concave portion CV1 of the first organic insulation layer OC1. The second concave portion CV2 of the second organic insulation layer OC2 can include a second flat surface S23 and a second slope surface S22 each provided at a height which is lower than the first flat surface S21. The second slope surface S22 can be disposed in at least one side of the second flat surface S23 and can be a surface which connects the first flat surface S21 to the second flat surface S23. At least a portion of the second slope surface S22 can overlap with the first slope surface S12 of the first organic insulation layer OC1. In FIG. 10, it is illustrated that the second flat surface S23 is formed at the second concave portion CV2, but embodiments of the present disclosure are not limited thereto. In the second concave portion CV2 of the second organic insulation layer OC2, the second flat surface S23 can be omitted based on a separation distance between the subpixels SP1 to SP3 or the viscosity of an organic material of the second organic insulation layer OC2. Alternatively, in the second concave portion CV2 of the second organic insulation layer OC2, the second flat surface S23 may not be a flat surface.

The second slope surface S22 of the second organic insulation layer OC2 can have a second slope θ2 which is lower than the first slope surface S12 of the second organic insulation layer OC1. In an embodiment, the second slope θ2 can be 45 degrees or less.

The second slope surface S22 can have the second slope θ2 which is lower or more gentle, and thus, the second organic insulation layer OC2 can have a second thickness T2 which is relatively thin. When the second thickness T2 of the second organic insulation layer OC2 is thick, a horizontal distance of the second slope surface S22 of the second organic insulation layer OC2 can increase so that the second slope θ2 is formed to be 45 degrees or less. As the horizontal distance of the second slope surface S22 of the second organic insulation layer OC2 increases, the separation distance between the subpixels SP1 to SP3 may increase. Accordingly, the display panel 110 may decrease in aperture ratio. In the display panel 110 according to another embodiment of the present disclosure, the second thickness T2 of the second organic insulation layer OC2 can be formed to be thin, and thus, the second slope θ2 of the second slope surface S22 of the second organic insulation layer OC2 can be formed to be 45 degrees or less and the separation distance between the subpixels SP1 to SP3 may not increase and the subpixels can be disposed closer together.

The second organic insulation layer OC2 can include an organic material. The thickness and planarization characteristic of an organic material can be changed based on viscosity. The second organic insulation layer OC2 can include an organic material having a second viscosity which is low. For example, the second organic insulation layer OC2 can include polyimide (PI) or siloxane-group organic material. The second organic insulation layer OC2 can have the second thickness T2 which is thin compared to the first organic insulation layer OC1 and can allow planarization not to be implemented in the second concave portion CV2. Accordingly, the second organic insulation layer OC2 can sufficiently secure an area of the second slope surface S22 in the second concave portion CV2.

In the display panel 110 according to another embodiment of the present disclosure, the first organic insulation layer OC1 having a good planarization characteristic can be formed to completely cover the color filters CF1 and CF2 even in areas between adjacent subpixels. Accordingly, the second organic insulation layer OC2 which is not relatively good in planarization characteristic may not always completely cover the color filters CF1 and CF2, but since the first organic insulation layer OC1 can adequately secure coverage, a gas caused by outgassing can be assuredly prevented from moving to the light emitting device ED. In other words, the first organic insulation layer OC1 can provide a type of back-up coverage to prevent outgassing if portions of the second organic insulation layer OC2 happen to become disconnected between adjacent subpixels.

The above-described features, structures, and effects of the present disclosure are included in at least one embodiment of the present disclosure, but are not limited to only one embodiment. Furthermore, the features, structures, and effects described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A display panel, comprising:
a first subpixel and a second subpixel disposed on a substrate, the first subpixel being adjacent to the second subpixel, and each of the first and second subpixels including a first electrode, an emission layer and a second electrode;
a first insulation layer disposed between the emission layer and the substrate, the first insulation layer including a first concave portion disposed between a first emission area of the first subpixel and a second emission area of the second subpixel; and
a second insulation layer disposed between the emission layer and the first insulation layer, the second insulation layer including a second concave portion disposed between the first emission area and the second emission area,
wherein the second electrode extends across the second concave portion of the second insulation layer,
wherein a portion of the second electrode is disposed in the second concave portion, and
wherein the portion of the second electrode is located closer to the substrate than both of the first electrode in the first subpixel and the first electrode in the second subpixel, or is located closer to the substrate than an upper surface of the first insulation layer.

2. The display panel of claim 1, further comprising:
a color filter layer disposed in at least one of the first subpixel and the second subpixel,
wherein the first insulation layer includes an opening region exposing at least a portion of the color filter layer.

3. The display panel of claim 1, wherein the portion of the second electrode is configured to reflect light emitted from at least one of the first and second emissions areas in a direction toward the substrate.

4. The display panel of claim 1, wherein the second insulation layer has a second refractive index that is greater than a first refractive index of the first insulation layer.

5. The display panel of claim 1, wherein a first thickness of the first insulation layer in an area overlapping with the first or second emission area is greater than a second thickness of the second insulation layer in an area overlapping with the first or second emission area.

6. The display panel of claim 5, wherein the second insulation layer has a third thickness corresponding to a center of the second concave portion, and
wherein the third thickness is less than or equal to the second thickness.

7. The display panel of claim 1, wherein the first insulation layer includes a first slope surface corresponding to the first concave portion,
wherein the second insulation layer includes a second slope surface corresponding to the second concave portion, and
wherein the first slope surface is steeper than the second slope surface.

8. The display panel of claim 7, wherein the emission layer extends across both of the first and second subpixels,
wherein the emission layer includes a third slope surface corresponding to the second slope surface of the second insulation layer,
wherein the second electrode includes a fourth slope surface corresponding to the third slope surface of the emission layer, and
wherein an angle of the fourth slope surface of the second electrode corresponds to an angle of the second slope surface of the second insulation layer.

9. The display panel of claim 1, wherein a lowermost portion of the second electrode between the first and second subpixels is disposed closer to the substrate than an upper surface of the first insulation layer.

10. The display panel of claim 1, wherein the first insulation layer includes an opening region corresponding to the first concave portion, the opening region being a hole that extends through opposite sides of the first insulation layer.

11. The display panel of claim 1, further comprising:
a bank disposed on an edge of the first electrode in the first subpixel and on an edge of the first electrode in the second subpixel.

12. The display panel of claim 1, wherein both of the first and second insulation layers extend continuously across a non-emission area between the first subpixel and the second subpixel, and
wherein the first insulation layer includes a first flat surface overlapping with at least one of the first and second emission areas, and a second flat surface overlapping with the non-emission area between the first subpixel and the second subpixel, the second flat surface being disposed closer to the substrate than the first flat surface.

13. The display panel of claim 1, wherein a cross section of the second electrode has a “V” shape or a “U” shape in a non-emission area between the first subpixel and the second subpixel.

14. The display panel of claim 1, wherein the emission layer extends across both of the first and second subpixels,
wherein an outer edge of the first electrode in the first subpixel facing towards the first and second concave portions directly contacts the emission layer, and
wherein an outer edge of the first electrode in the second subpixel facing towards the first and second concave portions directly contacts the emission layer.

15. The display panel of claim 1, wherein a first slope surface of the first insulation layer has a slope which is greater than or equal to 70 degrees, and
wherein a second slope surface of the second organic insulation layer has a slope which is less than or equal to 45 degrees.

16. A display apparatus comprising:
a first organic insulation layer disposed on a substrate, the first organic insulation layer including a first slope surface between a first subpixel and a second subpixel;
a second organic insulation layer disposed on the first organic insulation layer, the second organic insulation layer including a second slope surface between the first subpixel and the second subpixel and at least partially overlapping with the first slope surface; and
a plurality of light emitting devices respectively disposed in the first subpixel and the second subpixel, on the second organic insulation layer,
wherein the second slope surface of the second organic insulation layer has a slope which is less than a slope of the first slope surface of the first organic insulation layer.

17. The display apparatus of claim 16, wherein the first organic insulation layer is thicker than the second organic insulation layer.

18. The display apparatus of claim 16, wherein the first organic insulation layer has a lower refractive index than the second organic insulation layer.

19. The display apparatus of claim 16, wherein the first slope surface of the first organic insulation layer has a slope which is greater than or equal to 70 degrees.

20. The display apparatus of claim 16, wherein the second slope surface of the second organic insulation layer has a slope which is less than or equal to 45 degrees.

21. The display apparatus of claim 16, wherein the first organic insulation layer includes an organic material having a viscosity which is higher than a viscosity of the second organic insulation layer.

22. The display apparatus of claim 16, wherein the first organic insulation layer includes an opening region between the first subpixel and the second subpixel, and
wherein the second organic insulation layer covers the opening region of the first organic insulation layer.

23. The display apparatus of claim 16, wherein a thickness of the second organic insulation layer between the first subpixel and the second subpixel is thinner than a thickness of the second organic insulation layer in a region overlapping the first subpixel.

24. The display apparatus of claim 16, wherein the first organic insulation layer further includes a first flat surface in a region overlapping the first subpixel and a second flat surface disposed at a lower height than the first flat surface in a region between the first subpixel and the second subpixel, and
wherein the first slope surface connects the first flat surface to the second flat surface.

25. The display apparatus of claim 16, further comprising a plurality of color filters respectively provided in the first subpixel and the second subpixel, between the substrate and the first organic insulation layer.

26. The display apparatus of claim 25, wherein the first organic insulation layer includes an opening region exposing at least a portion of each of the plurality of color filters, between the first subpixel and the second subpixel, and
wherein the second organic insulation layer covers the at least a portion of each of the plurality of color filters exposed by the opening region, between the first subpixel and the second subpixel.

27. The display apparatus of claim 25, wherein the plurality of color filters at least partially overlap each other between the first subpixel and the second subpixel.

28. The display apparatus of claim 16, wherein each of the plurality of light emitting devices includes:
a first electrode on the second organic insulation layer;
an emission layer on the first electrode; and
a second electrode on the emission layer,
wherein the second electrode is a reflection electrode.

29. The display apparatus of claim 28, wherein the emission layer extends continuously across the first subpixel and the second subpixel and between the first subpixel and the second subpixel, and the emission layer contacts an entire region of the first electrode.

30. The display apparatus of claim 28, wherein the second electrode extends continuously across the first subpixel and the second subpixel and between the first subpixel and the second subpixel, and the second electrode extends along the second slope surface of the second organic insulation layer, between the first subpixel and the second subpixel.

31. The display apparatus of claim 28, further comprising a bank disposed on the first electrode to cover an end of the first electrode.
